(19) United States
(12) Patent Application Publication
(10) Pub. No.: US 2025/0336792 A1
(43) Pub. Date: Oct. 30, 2025

(54) IC PACKAGE WITH CONNECTION PADS FOR DIE

(71) Applicant: TEXAS INSTRUMENTS INCORPORATED, DALLAS, TX (US)

(72) Inventors: KUAN-TING LIU, Taichung City (TW); BOB LEE, ZHONGHE DIST (TW)

(21) Appl. No.: 18/649,482

(22) Filed: Apr. 29, 2024

(51) Int. Cl. H01L 23/498; H01L 21/48; H01L 23/00

(52) U.S. Cl. CPC H01L 23/49838; H01L 21/4853; H01L 21/4857; H01L 23/49811; H01L 23/49822; H01L 24/16; H01L 24/81; H01L 2224/16238; H01L 2224/81447; H01L 2224/81815

(57) ABSTRACT

An IC (integrated circuit) package includes a first interconnect. The first interconnect includes a first surface having connection pads. The connection pads include pillars extending in a direction normal to the first surface and a second surface opposing the first surface having connection pads for leads. The IC package also includes a second interconnect including the leads mounted on the connection pads of the second surface of the first interconnect and a die mounted with solder bumps on the connection pads of the first surface of the first interconnect. A portion of the solder bumps flow over the pillars.

### TECHNICAL FIELD

This disclosure relates to IC (integrated circuit) packages that include an interconnect with connection pads for a die.

### BACKGROUND

ICs (integrated circuits) packages are the cornerstone of modern electronics, found in everything from computers and mobile devices to automobiles and industrial machinery. As the demand for smaller, faster and more energy-efficient devices continues to grow, the semiconductor industry is challenged to improve IC packaging technologies to meet these demands.

Conventionally, IC packages have been constructed using an interconnect (alternatively referred to as a leadframe) as a support structure, providing mechanical stability, electrical connectivity and heat dissipation for a semiconductor die. The leadframe includes a die pad for mounting the semiconductor die. One of the challenges in IC packaging is the formation of reliable solder joints between the die and the interconnect. Cracking of solder joints leads to failure of the IC package.

### SUMMARY

A first example relates to an IC (integrated circuit) package that includes a first interconnect. The first interconnect includes a first surface having connection pads. The connection pads include pillars extending in a direction normal to the first surface and a second surface opposing the first surface having connection pads for leads. The IC package also includes a second interconnect including the leads mounted on the connection pads of the second surface of the first interconnect and a die mounted with solder bumps on the connection pads of the first surface of the first interconnect. A portion of the solder bumps flow over the pillars.

A second example relates to a method for forming an IC package. The method includes forming connection pads that extend between a top surface and a bottom surface of an interconnect. The method also includes forming pillars on a portion of the connection pads that are exposed on the top surface of the interconnect. The pillars extend in a directional normal to the top surface of the interconnect.

### BRIEF DESCRIPTION OF THE DRAWINGS

FIG. 1A illustrates an example of an IC package that includes a first interconnect with pillars on connection pads.

FIG. 1B illustrates a zoomed-in view of a region of the IC package of FIG. 1A that includes a pillar and solder to form a solder bump between a connection node of a die and the connection pad of the first interconnect.

FIG. 2A illustrates an IC package that includes a first interconnect with a first die and a second die mounted on a top surface of the first interconnect.

FIG. 2B illustrates the first interconnect of FIG. 2A with other components removed for clarity.

FIG. 2C illustrates a zoomed-in version of the region of the first interconnect of FIG. 2B.

FIG. 3 illustrates a simplified diagram of a solder bump formed with a copper pillar.

FIG. 4A illustrates a heat map of an IC package during a temperature profile test.

FIG. 4B illustrates another heat map during the temperature profile test of the IC package of FIG. 4A where a mold compound of is removed.

FIG. 4C illustrates a strain distribution map during the temperature profile test for the IC package of FIGS. 4A and 4B.

FIG. 5 Illustrates a chart that plots a strain of the IC package of FIG. 4A-4C that includes pillars as a function of time during the temperature profile test.

FIG. 6 illustrates a stress distribution chart for a region of an IC package with maximum strain depicted by a marker of FIG. 4C.

FIG. 7 illustrates a bar chart that compares a maximum sheer stress for a region of the IC package depicted by a marker of FIG. 4C.

FIGS. 8-23 illustrate stages of a method for fabricating an IC package.

FIG. 24 illustrates a flowchart of an example method for forming an IC package.

FIG. 25 illustrates a flowchart of an example sub-method for forming pillars on an interconnect for the IC package formed by the method of FIG. 24.

### DETAILED DESCRIPTION

This description relates to an IC package, and a method for fabricating the IC package that enhances the structural integrity and electrical performance of the IC package. The IC package includes of an interconnect (alternatively referred to as a routable leadframe) that has connection pads for a die. Pillars, such are copper pillars are formed on these connection pads to facilitate robust solder joint formation, particularly beneficial in fine-pitch applications.

These pillars are created on the surface of the interconnect where solder will be applied (the connection pads), and the pillars are designed to extend in a direction normal to the surface of the interconnect. The copper pillars are formed using a process that includes depositing a photoresist layer, patterning the photoresist to expose portions of the interconnect, electroplating copper to form the pillars and removing the photoresist layer. In some examples, the pillars have a cylindrical shape, such that the pillars have a circular cross-section.

The pillars provide several advantages. The pillars offer a high degree of precision in the placement of solder, which is helpful as the spacing between connections becomes increasingly narrow in modern IC designs. Additionally, the material chosen for the pillars (e.g., copper) has favorable thermal and electrical properties, which contribute to the overall performance of the IC package.

Once the copper pillars are formed, solder is applied to pillars in preparation for the reflow process. This solder application can be achieved through various techniques, including screen printing or other deposition methods. The solder is reflowed to create a mechanical and electrical bond between the die and the interconnect.

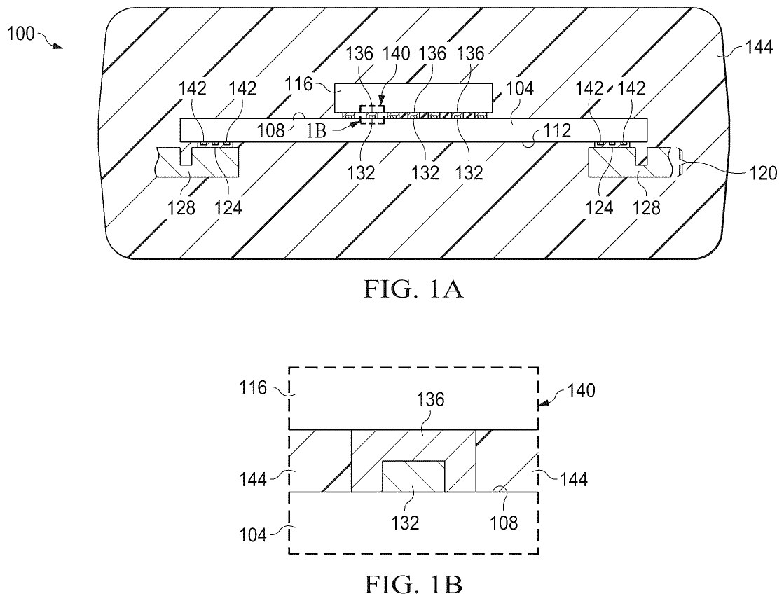

FIG. 1A illustrates an example of an IC package 100 that includes a first interconnect 104, that is alternatively referred to as a routable leadframe, or just a leadframe. The first interconnect 104 includes a top surface 108 (e.g., a first surface) and a bottom surface 112 (e.g., a second surface) that opposes the top surface 108. The first interconnect 104 includes connection pads (conductive traces) that extend between the top surface 108 and the bottom surface 112.

A die 116 (e.g., a semiconductor die) is mounted on the connection pads on the top surface 108 of the first interconnect 104. Additionally, the first interconnect 104 is mounted on a second interconnect 120 with solder bumps 124. The second interconnect 120 includes leads 128 for connecting the IC package 100 to external components, such as components on a PCB (printed circuit board). In some examples, the first interconnect 104 is coated with an isolation layer made of material such as ABF (Ajinomoto build-up film) disposed between the first interconnect 104 and the die 116 to improve electrical isolation of the die 116. In some examples, the isolation layer (the ABF) is applied to the first interconnect 104 prior to mounting the die 116.

The top surface 108 of the first interconnect 104 includes pillars 132 on the connection pads exposed at the top surface 108. The pillars 132 extend in a direction normal to the top surface 108 of the first interconnect 104. The pillars 132 have a circular cross section, and in some examples, the pillars 132 have a diameter within a range of about 3-13 micrometers (μm), such as about 5 to about 10 μm. The pillars 132 are copper pillars in some examples. In other examples, the pillars 132 are formed of a different material. The pillars 132 facilitate the flow of solder 136 between connection nodes (alternatively referred to as connection pads or contact pads) on the die 116 and the connection pads of the top surface 108 of the first interconnect 104.

FIG. 1B illustrates a zoomed-in view of a region 140 that includes a single pillar 132 and solder 136 to form a solder bump between a connection node of the die 116 and the connection pad of the first interconnect 104. However, the other pillars 132 illustrated in FIG. 1A have similar features. The pillar in encased by the solder 136, such that solder flows around a top and sides of the pillar 132.

Referring back to FIG. 1A, in some examples, the pillars 132 on the top surface 108 are considered a first set of pillars, and the bottom surface 112 of the first interconnect 104 includes a second set of pillars 142 that contact the solder bumps 124.

The first interconnect 104, the die 116 and a portion of the second interconnect 120 are encapsulated in a mold compound 144, such as plastic. Features of the IC package 100 have different CTEs (coefficients of thermal expansion). For instance, in some examples, the first interconnect 104 has a CTE of about 13 micrometers per degree Celsius (μm/° C.), the die 116 has a CTE of about 8 μm/° C. and the second interconnect 120 has a CTE of about 16 μm/° C. Thus, the largest difference in CTE is between the first interconnect 104 and the die 116. Additionally, there is a smaller difference in CTE between the first interconnect 104 and the second interconnect 120. In a conventional approach (where the first set of pillars 132 and/or the second set of pillars 142 are not included), these differences in CTE can lead to cracking of the solder 136 and/or the solder bumps 124. However, the first set of pillars 132 and/or the second set of pillars 142 provide an anchorage effect to improve the reliability of joints between the first interconnect 104 and the die 116 and/or between the first interconnect 104 and the second interconnect 120. Moreover, in the event that a crack in the solder 136 does occur, the pillars 132 on the top surface 108 prevent spreading of the crack, thereby curtailing delamination of the die 116, and improving overall performance and reliability of the IC package 100. Also, the second set of pillars 142 prevent the spread of cracks in the solder bumps 124 in a similar manner.

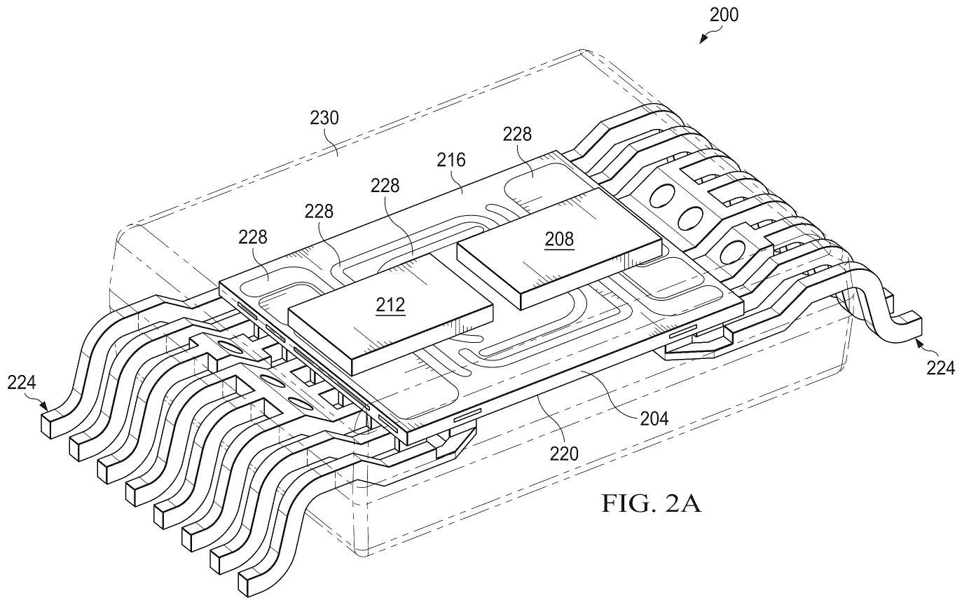

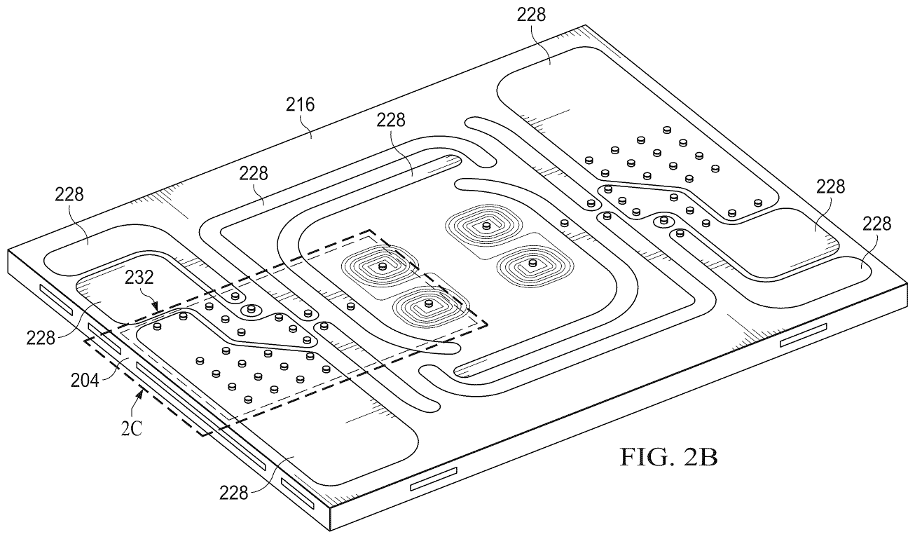

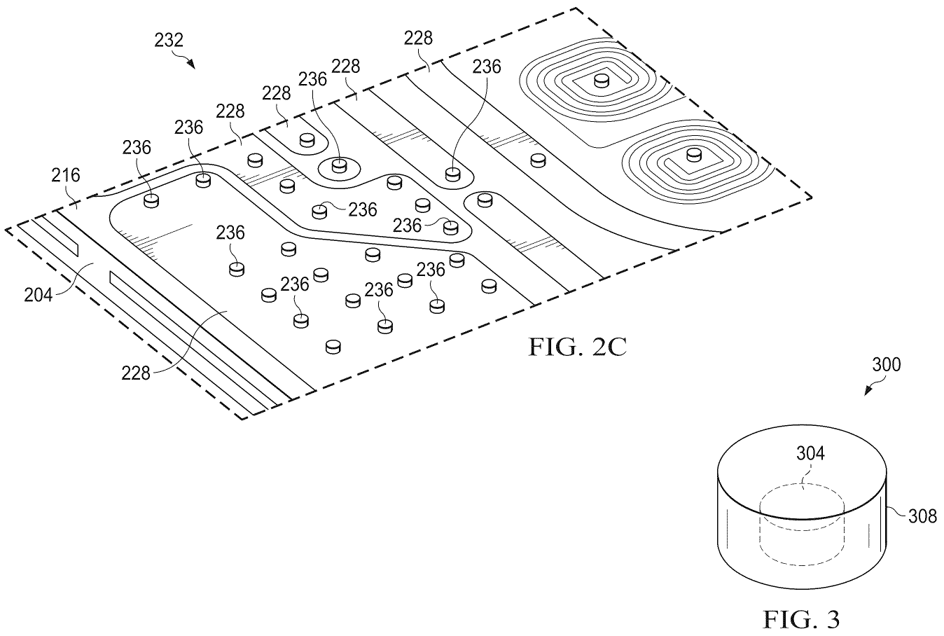

FIGS. 2A-2C illustrate components of an IC package 200. Moreover, FIGS. 2A-2C employ the same reference numbers to denote the same structures. The IC package 200 is employable to implement the IC package 100 of FIG. 1A.

More specifically, FIG. 2A illustrates the IC package 200 that includes a first interconnect 204 with a first die 208 and a second die 212 mounted on a top surface 216 (e.g., a first surface) of the first interconnect 204. The first interconnect 204 is alternatively referred to as a routable leadframe. A bottom surface (e.g., a second surface) of the first interconnect 204 is mounted on a second interconnect 220 that includes leads 224. The leads 224 are trimmed and formed to enable connections to external components, such as components mounted on a PCB.

The first interconnect 204 includes connection pads 228 on the top surface 216. Some of the connection pads 228 extend between the top surface 216 and the bottom surface. Accordingly, the first die 208 and the second die 212 illustrated in are coupled to the leads 224. Additionally, some of the connection pads 228 enable communication between the first die 208 and the second die 212. A mold compound 230 (e.g., plastic) encapsulates the first interconnect 204, the first die 208, the second die 212 and a portion of the second interconnect 220.

FIG. 2B illustrates the first interconnect 204 with other components removed for clarity. The first interconnect 204 includes the connection pads 228 on the top surface 216. As noted, some of the connection pads 228 extend between the top surface 216 and the bottom surface. The first interconnect 204 is coated with ABF (Ajinomoto build-up film) in some examples. This ABF provides an electrical isolation layer disposed between the first interconnect 204 and a die mounted thereon (the first die 208 and/or the second die 212 of FIG. 1A). In some situations, the ABF is applied to the first interconnect 204 prior to mounting such dies. Also, FIG. 2B includes a region 232, and FIG. 2C illustrates a zoomed-in version of the region 232.

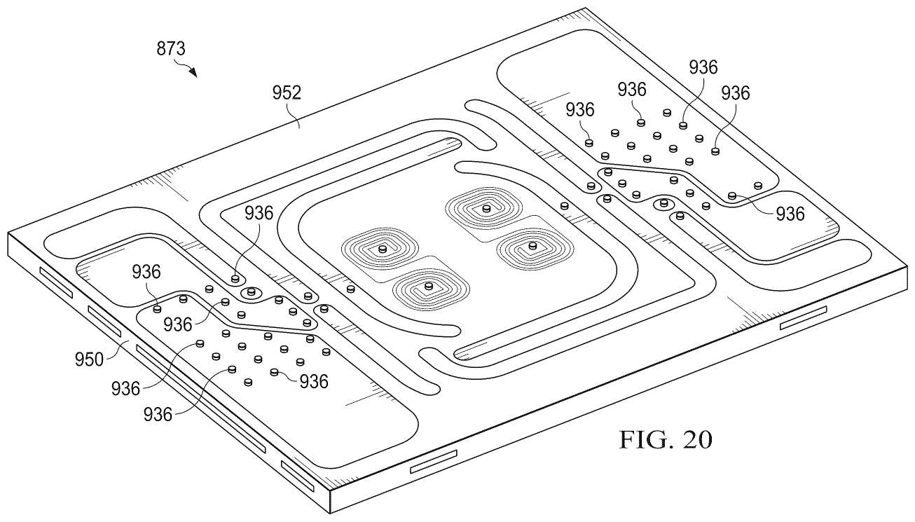

As illustrated in FIG. 20, the connection pads 228 include multiple pillars 236 (same as the pillars 132 in FIGS. 1A and 1B), only some of which are labeled. The pillars 236 are formed of the same material as the connection pads 228, namely a conductive material, such as copper. The pillars 236 extend in a direction normal to the top surface 216. Moreover, the pillars 236 have a cylindrical shape with a circular cross-section. In some examples, the pillars 236 have a diameter of about 3 to about 13 μm.

The pillars 236 provide an anchorage effect for attaching the first die 208 and the second die 212 to the first interconnect 204. More specifically, solder between the first die 208 and the first interconnect 204 and solder between the second die 212 and the first interconnect 204 encases the pillars 236. Thus, the pillars 236 provide mechanical resistance to cracking, and distribute stress and strain caused by thermal expansion of the first die 208 and the second die 212 and the first interconnect 204.

FIG. 3 illustrates a simplified diagram of a solder bump 300 formed with a copper pillar 304, such as one of the pillars 236 of FIG. 2C. The copper pillar 304 extends in a directional normal to a surface of an interconnect, such as the top surface 216 of FIGS. 2A-2C. Solder 308 encases the copper pillar 304, flowing over a top and sides of the copper pillar 304.

Referring back to FIG. 2A, during operation, the pillars 236 curtail cracking caused by thermal expansion. Additionally, should a crack in solder occur, the pillars 236 prevent and/or impede such a crack from expanding, thereby reducing a chance of delamination of the first die 208 and the second die 212 from the first interconnect 204.

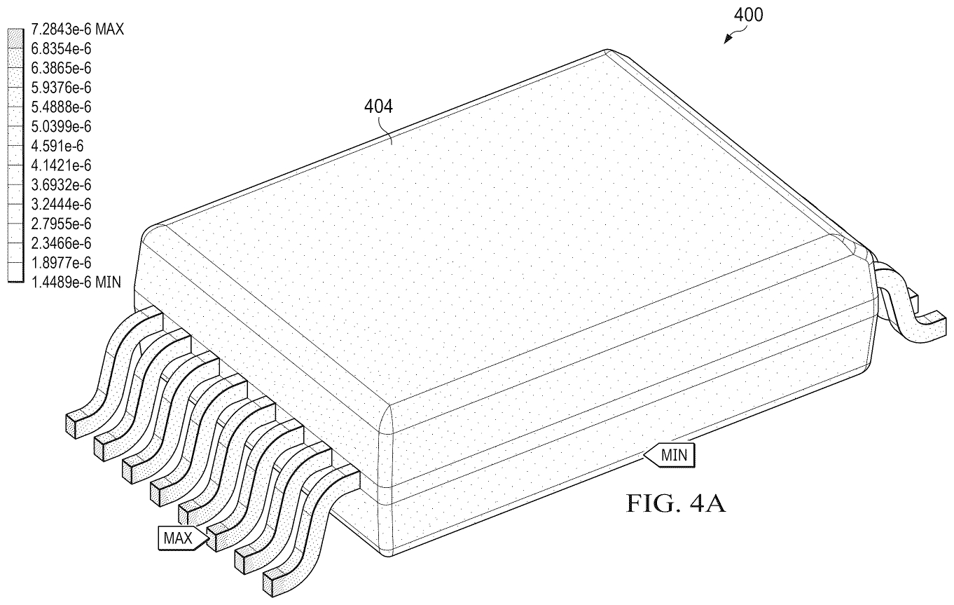

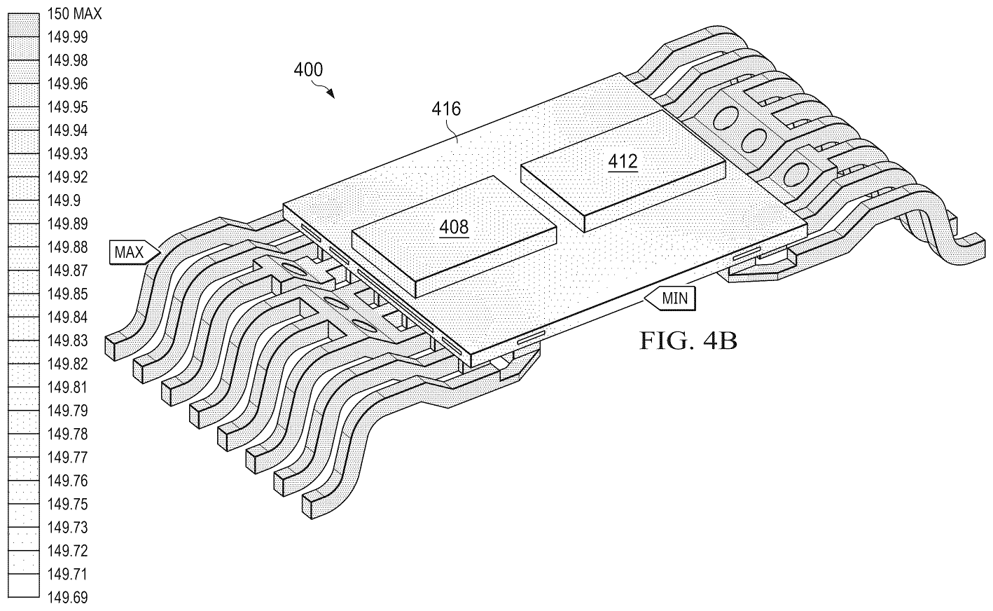

FIGS. 4A-4B illustrate heat maps of an IC package 400 during a thermal profile test. The IC package 400 includes pillars, such as the pillars 236 of FIG. 2A-2C. During the thermal profile test, a temperature of the IC package 400 is raised from about −55° C. to about 150° C. and lowered back to −55° C. over a time of about 800 seconds. This temperature cycle is executed twice, and the heat of the IC package 400 is recorded during the temperature profile test. In the diagrams illustrated in FIG. 4A-4B, it is presumed that the heat shown is for a peak temperature (e.g., about 150° C.) of the temperature profile test.

FIG. 4A illustrates the IC package 400 wherein a mold compound 404 is included. FIG. 4B illustrates the IC package 400 where the mold compound 404 is removed to show the heat map for a first die 408, a second die 412 and a first interconnect 416.

FIG. 4C illustrates a strain distribution map for the IC package 400. FIG. 4C employs the same reference numbers as FIG. 4A and 4B to denote the same structure. Additionally, the strain distribution map includes a marker 430 that denotes a point with a greatest strain, caused by a difference in thermal expansion of the first die 408 and the first interconnect 416.

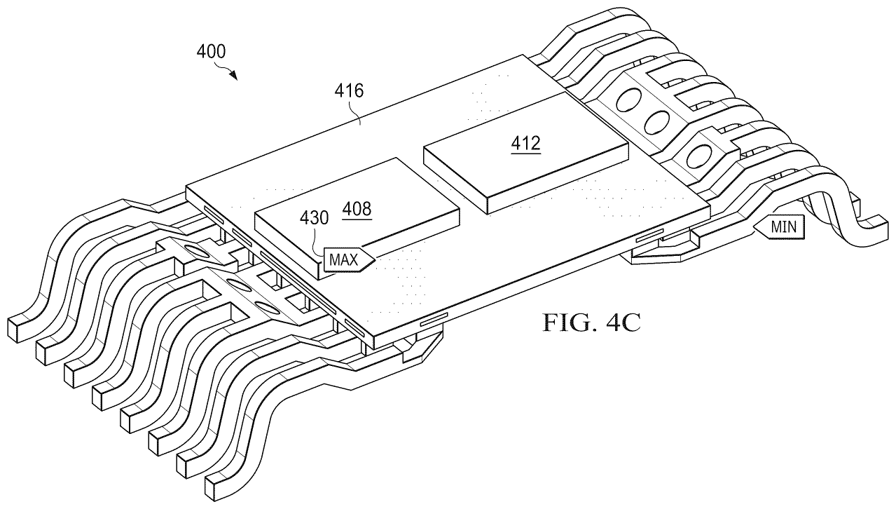

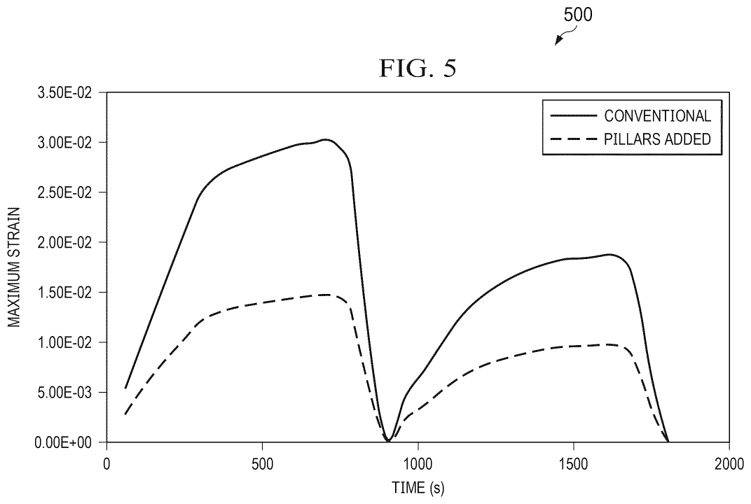

FIG. 5 Illustrates a chart 500 that plots a strain of the IC package 400 of FIG. 4A-4C that includes pillars (e.g., the pillars 236 of FIG. 2A-2C) as a function of time during the temperature profile test. The chart 500 also plots a strain of a conventional IC package that omits pillars. As illustrated, including the pillars reduces the maximum strain from about 3.00E−02 to about 1.5E−02 during the first temperature cycle of the temperature profile test. Additionally, including the pillars reduces the maximum strain from about 1.80E−02 to about 1.00E−02 during the second temperature cycle of the temperature profile test.

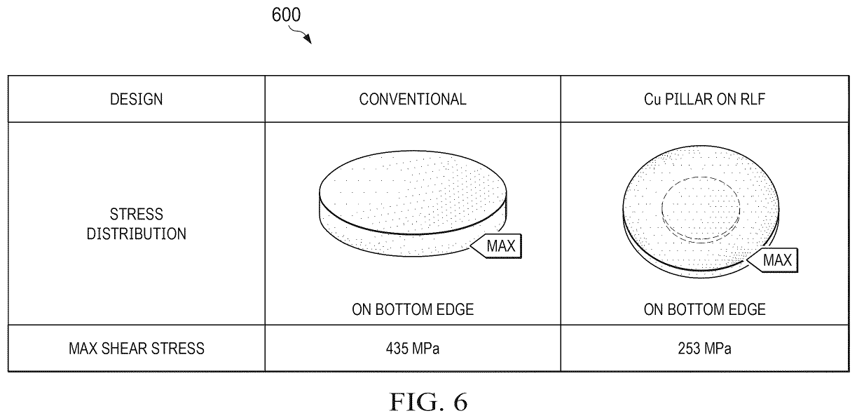

FIG. 6 illustrates a stress distribution chart 600 for the region of the IC package 400 with maximum strain depicted by the marker 430 of FIG. 4C. The chart 600 includes a stress distribution for a conventional approach where the pillars are omitted, and a stress distribution where the pillars are included, such as the IC package 400 of FIGS. 4A-4C. As illustrated, including the pillars reduces a maximum shear stress from about 435 mega Pascals (MPa) to about 253 MPa.

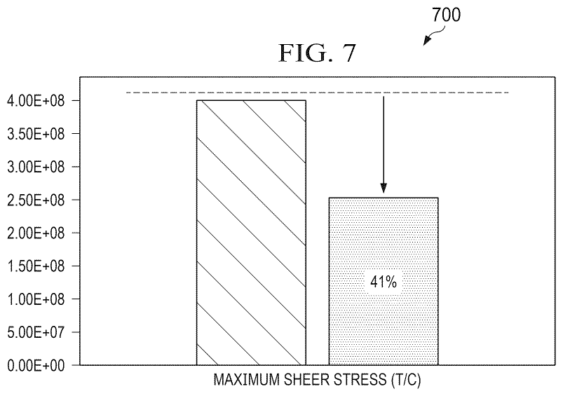

FIG. 7 illustrates a bar chart 700 that compares a maximum sheer stress for a region of the IC package 400 depicted by the marker 430 of FIG. 4C. The chart 700 includes a maximum shear stress distribution for a conventional approach where the pillars are omitted, and a maximum sheer stress where the pillars are included, such as the IC package 400 of FIGS. 4A-4C. As illustrated, including the pillars reduces a maximum shear stress by about 41%, consistent with the stress distribution chart 600 of FIG. 6.

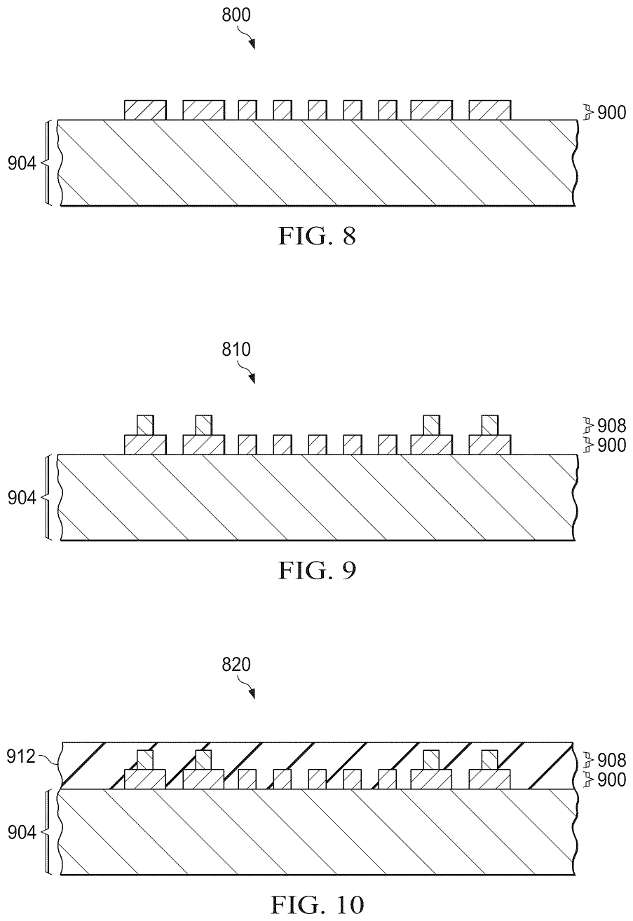

FIGS. 8-23 illustrate stages of a method for fabricating an IC package such as the IC package 100 of FIG. 1A and/or the IC package 200 of FIG. 2A. The method of FIGS. 8-23 illustrate how pillars are added to an interconnect (e.g., a routable leadframe).

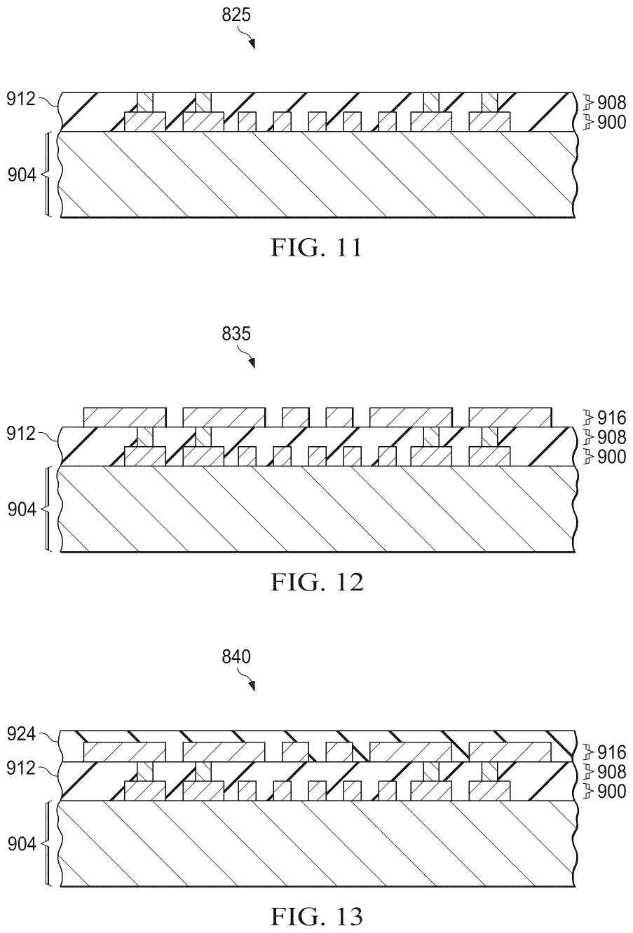

As illustrated in FIG. 8, at 800, in a first stage, a first metal layer pattern 900 is plated on a metal carrier 904. As illustrated in FIG. 9, in a second stage, at 810, pillars 908 (e.g., copper pillars or pillars formed of other metal) are plated on the first metal layer pattern 900. As illustrated in FIG. 10, at 820, in a third stage, a first dielectric layer 912 is applied in a compressed molding operation to the pillars 908 and to the first metal layer pattern 900. As illustrated in FIG. 11, in a fourth stage, at 825, a portion of the first dielectric layer 912 is removed in a grinding operation, such that regions of the pillars 908 are exposed.

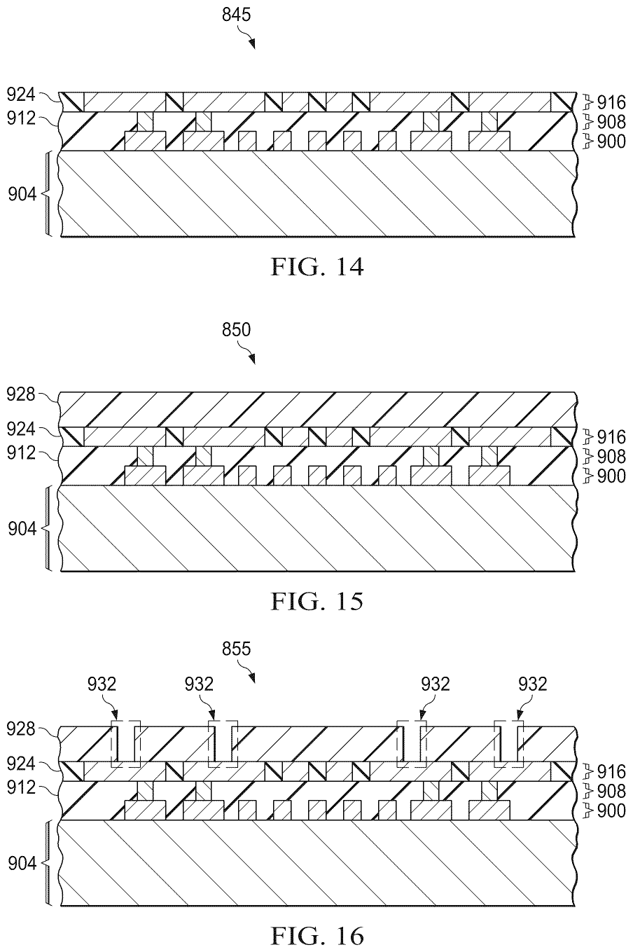

As illustrated in FIG. 12, in a fifth stage, at 835, a second metal layer pattern 916 is plated on the first dielectric layer 912. As illustrated in FIG. 13, in a sixth stage, at 840 a second dielectric layer 924 is applied in a compressed molding operation to the pillars 908 and to the second metal layer pattern 916. As illustrated in FIG. 14, in a seventh stage, at 845, a portion of the second dielectric layer 924 is removed in a grinding operation, such that regions of the second metal layer pattern 916 (connection pads) are exposed.

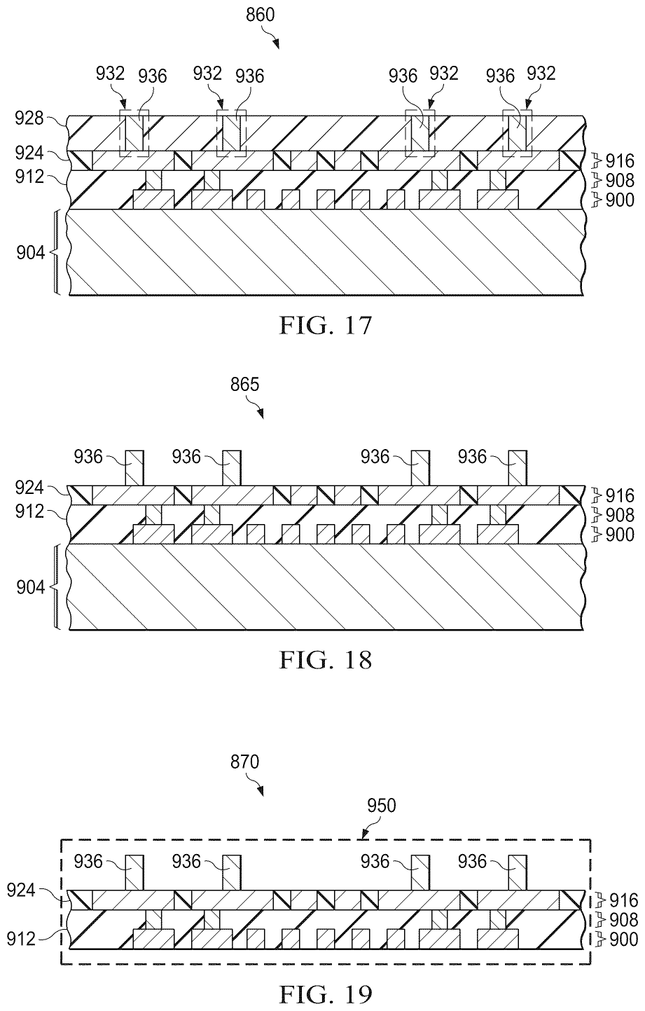

As illustrated in FIG. 15, in an eighth stage, at 850, a layer of dry film 928 (e.g., a photoresist layer) is overlaid on the second dielectric layer 924 and the second metal layer pattern 916. As illustrated in FIG. 16, in a ninth stage at 855, the layer of dry film 928 is etched to provide voids 932 with a circular cross-section. As illustrated in FIG. 17, in a tenth stage, at 860, a conductive material, such as copper is plated in the voids 932 to form pillars 936. As illustrated in FIG. 18, in an eleventh stage at 865, the remaining dry film 928 is removed (stated differently, the remaining photoresist layer is removed) to expose sides of the pillars 936. As illustrated in FIG. 19, in a twelfth stage at 870, the metal carrier 904 is removed in a de-carrier operation to provide a first interconnect 950 (e.g., a routable leadframe). The de-carrier operation executed at 870 exposes a region of the first metal layer pattern 900 to enable the second metal layer pattern 916 (connection pads) to be conductively coupled to connection pads formed on the first metal layer pattern 900.

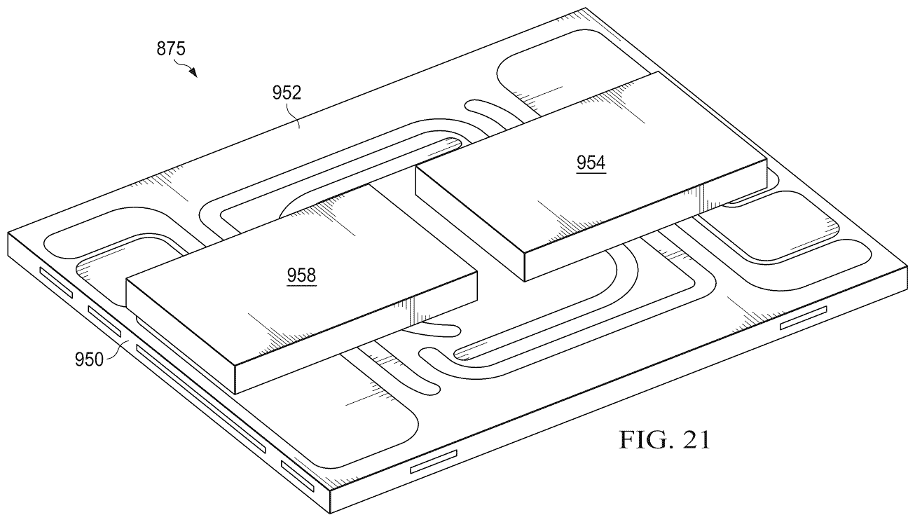

As illustrated in FIG. 20, in a thirteenth stage at 873, the first interconnect 950 is provided (e.g., in an isometric view). The first interconnect 950 is employable to implement the first interconnect 104 of FIG. 1A and/or the first interconnect 204 of FIGS. 2A-2B. Thus, the first interconnect 950 includes the pillars 936 on connection pads that are on a top surface 952 (e.g., a first surface) of the first interconnect 950. The first interconnect 950 may also include pillars (corresponding to the second set of pillars 142 in FIG. 1A) on a bottom surface of the first interconnect 950 (corresponding to the bottom surface 112 in FIG. 1A on the first interconnect 104 using the same operations to form the first set of pillars 132 for the surface 108 of the first interconnect 104). As illustrated in FIG. 21, in a fourteenth stage at 875, a first die 954 and a second die 958 are mounted on the top surface 952 of the first interconnect 950 using a flip-chip technique with a solder reflow operation. The solder encases the pillars formed on the connection pads.

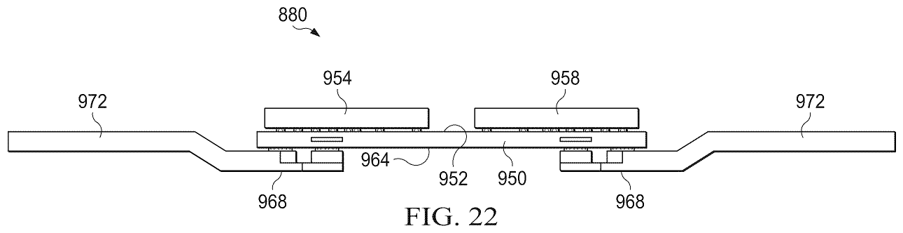

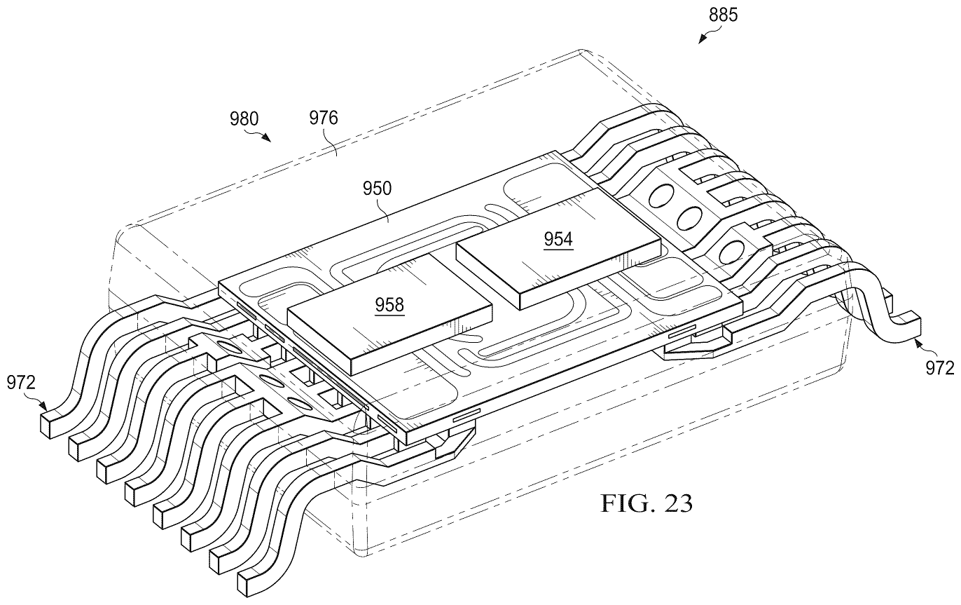

As illustrated in FIG. 22, in a fifteenth stage at 880, a bottom surface 964 of the first interconnect 950 is mounted on a second interconnect 968 that includes pillars (corresponding to the second set of pillars 142 in FIG. 1A) on the bottom surface of the first interconnect 950 to respective leads 972 with a solder reflow operation. The solder encases the pillars formed on the connection pads. Optionally, forming pillars on the metal layer contacts on the bottom surface of the first interconnect 950 may be omitted with solder paste or solder balls being formed on the leads 972 or the metal contacts on the bottom surface of the first interconnect 950 after which a reflow operation will use the solder to make conductive connections between respective ones of the metal contacts on the bottom surface of the first interconnect 950 and the leads 972. As illustrated in FIG. 23, in a sixteenth stage at 885, the first interconnect 950, the first die 954, the second die 958 and a portion of the second interconnect 968 is encapsulated in a mold compound 976 through a mold flow operation. Additionally, at 885, the leads 972 are trimmed and formed to provide an IC package 980.

As illustrated in FIGS. 8-23, by implementing the method, the pillars 936 are formed with few operations, namely the operations at 850 of FIG. 15, 855 of FIG. 16, 860 of FIGS. 17 and 865 of FIG. 18. Thus, the benefits of the pillars 936 (reduced stress and strain during temperature cycles) is achieved with adding relatively few processing operations to form the IC package 980.

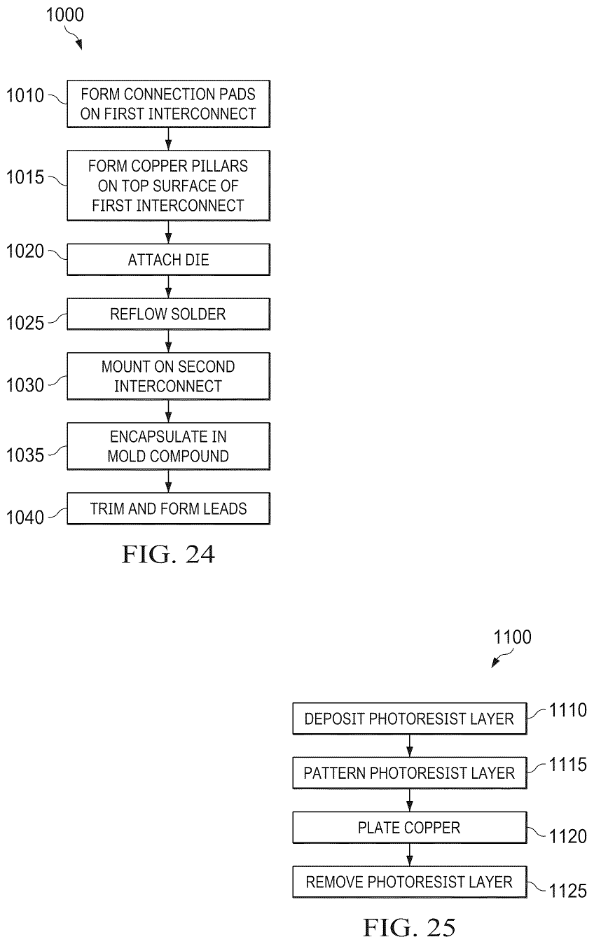

FIG. 24 illustrates a flowchart of an example method 1000 for forming an IC package (e.g., the IC package 100 of FIG. 1A and/or the IC package 200 of FIG. 2A). At block 1010, connection pads that extend between a top surface and a bottom surface of a first interconnect (e.g., the first interconnect 104 of FIG. 1A) are formed.

At block 1015, pillars (e.g., copper pillars, such as the pillars 132 of FIG. 1A) are formed on a portion of the connection pads that are exposed on the top surface of the first interconnect. The pillars extend in a directional normal to the top surface of the interconnect. FIG. 25 illustrates a flowchart of an example sub-method 1100 for forming the pillars, as describe in block 1015 of FIG. 24. At block 1110, a photoresist layer (e.g., the dry film 928 of FIG. 15) is deposited over the top surface of the first interconnect. At block 1115, the photoresist layer is patterned to expose portions of the connection pads where the pillars are to be formed. At block 1120, copper or other conductive material is plated onto the exposed portions of the connection pads to form the pillars with circular cross sections. At block 1125, the remaining portion of the photoresist layer is removed.

Referring back to FIG. 24, at block 1020, a die is attached to the top surface of the first interconnect such that connection nodes of the die overlay the connection pads of the top surface of the interconnect. At block 1025, solder is reflowed onto the pillars to form solder bumps for connecting the connection nodes of the die to the connection pads of the first interconnect.

At block 1030, a bottom surface of the first interconnect is mounted on a second interconnect (e.g., the second interconnect 120 of FIG. 1A) that includes leads (e.g., the leads 128 of FIG. 1A). At block 1035, the die, the first interconnect and a portion of the second interconnect is encapsulated in a mold compound. At 1040, the leads are trimmed and formed to provide the IC package.

In this description, unless otherwise stated, “about,” preceding a parameter means being within +/−10 percent of that parameter. Modifications are possible in the described embodiments, and other embodiments are possible, within the scope of the claims.

What is claimed is:

1. An IC (integrated circuit) package comprising:
a first interconnect comprising:
a first surface comprising connection pads, wherein the connection pads include pillars extending in a direction normal to the first surface; and
a second surface opposing the first surface having connection pads for leads;
a second interconnect comprising the leads mounted on the connection pads of the second surface of the first interconnect; and
a die mounted with solder bumps on the connection pads of the first surface of the first interconnect, wherein a portion of the solder bumps flow over the pillars.

2. The IC package of claim 1, wherein the connection pads and the pillars of the first surface of the first interconnect are formed with copper.

3. The IC package of claim 2, wherein the solder bumps have a first coefficient of thermal expansion and the copper has a second coefficient of thermal expansion that is different than the first coefficient of thermal expansion.

4. The IC package of claim 2, wherein the portion of the solder bumps encase the copper pillars.

5. The IC package of claim 1, wherein the pillars have a circular cross section.

6. The IC package of claim 5, wherein the pillars have a diameter of about 5 to about 10 micrometers.

7. The IC package of claim 1 further comprising an isolation layer made of ABF (Ajinomoto build-up film) disposed on the first interconnect to provide electrical isolation for the die.

8. The IC package of claim 1, wherein each connection pad of the connection pads includes multiple pillars.

9. The IC package of claim 1, wherein connection nodes on the die oppose the connection pads of the first interconnect.

10. The IC package of claim 1, wherein the pillars are a first set of pillars and the IC package further comprises a second set of pillars on the connection pads of the second surface of the first interconnect that extend in a direction normal to the second surface of the first interconnect.

11. A method for forming an IC (integrated circuit) package, the method comprising:
forming connection pads that extend between a top surface and a bottom surface of an interconnect; and
forming pillars on a portion of the connection pads that are exposed on the top surface of the interconnect, wherein the pillars extend in a directional normal to the top surface of the interconnect.

12. The method of claim 11, wherein forming the pillars further comprises:
depositing a photoresist layer over the top surface of the interconnect;
patterning the photoresist layer to expose portions of the connection pads where the pillars are to be formed;
electroplating copper onto the exposed portions of the connection pads to form the pillars; and
removing a remaining portion of the photoresist layer.

13. The method of claim 12, wherein the pillars have a circular cross section.

14. The method of claim 12, wherein the pillars have a diameter of about 5 to about 10 micrometers.

15. The method of claim 12, further comprising:
attaching a die on the top surface of the interconnect such that connection nodes of the die overlay the connection pads of the top surface of the interconnect; and
reflowing solder onto the pillars to form solder bumps for connecting die pads of the die to the connection pads of the interconnect.

16. The method of claim 15, further comprising applying ABF (Ajinomoto build-up film) to the interconnect prior to the attaching to increase electrical isolation.

17. The method of claim 15, wherein the solder bumps encase a portion of the pillars.

18. The method of claim 15, wherein the die is attached to the interconnect using a flip-chip mounting technique.

19. The method of claim 15, wherein the interconnect is a first interconnect, the method further comprising mounting the first interconnect on a second interconnect that includes leads, wherein connection pads on the bottom surface of the first interconnect are soldered to the leads.

20. The method of claim 19, further comprising encapsulating the die, the first interconnect and a portion of the leads of the second interconnect in a mold compound.
